(19) United States
(12) Patent Application Publication
(10) Pub. No.: US 2026/0089909 A1
(43) Pub. Date: Mar. 26, 2026

(54) SEMICONDUCTOR DEVICE HAVING HIGH DENSITY AND HIGH PERFORMANCE

(71) Applicant: TAIWAN SEMICONDUCTOR MANUFACTURING COMPANY, LTD., Hsinchu (TW)

(72) Inventor: Jhon Jhy LIAW, Hsinchu (TW)

(73) Assignee: TAIWAN SEMICONDUCTOR MANUFACTURING COMPANY, LTD., Hsinchu (TW)

(21) Appl. No.: 18/896,491

(22) Filed: Sep. 25, 2024

(51) Int. Cl. H10B 10/00

(52) U.S. Cl. CPC H10B 10/125

(57) ABSTRACT

In a semiconductor device, first to third metal layers are stacked from bottom to top over multiple transistors. Each transistor includes a gate electrode extending in a first direction. Each of multiple metal lines of the first metal layer extends in a second direction, and has a thickness of T1. Each of multiple metal lines of the second metal layer extends in the first direction, and has a thickness of T2. Each of multiple metal lines of the third metal layer extends in the second direction, and has a thickness of T3. One of T2/T1 and T2/T3 is greater than or equal to 1.2.

### BACKGROUND

The semiconductor integrated circuit (IC) industry has, over the decades, experienced tremendous advancements and is still undergoing vigorous development. With dramatic advances in technology, the industry pays much attention to the development of IC devices with high density and high performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating relative positions (in a Z direction) of various components of a semiconductor device in accordance with some embodiments.

FIGS. 2 to 4 are schematic diagrams illustrating relative positions (in an X direction and a Y direction) of various components of a semiconductor device in accordance with some embodiments.

FIGS. 5 to 7 are schematic diagrams illustrating relative positions (in an X direction and a Y direction) of various components of a semiconductor device in accordance with some embodiments.

FIG. 8 is a schematic diagram illustrating arrangement of standard cells of a semiconductor device in accordance with some embodiments.

FIG. 9 is a circuit diagram illustrating a static random access memory (SRAM) cell in accordance with some embodiments.

FIGS. 10 to 12 are schematic diagrams illustrating relative positions (in an X direction and a Y direction) of various components of an SRAM cell in accordance with some embodiments.

FIG. 13 is a schematic diagram illustrating relative positions (in an X direction and a Y direction) of some components of an SRAM cell in accordance with some embodiments.

FIG. 14 is a schematic sectional view of the SRAM cell taken along line A-A of FIG. 13 in accordance with some embodiments.

FIG. 15 is a schematic diagram illustrating relative positions (in an X direction and a Y direction) of some components of an SRAM device in accordance with some embodiments.

FIG. 16 is a schematic diagram illustrating relative positions (in a Z direction) of various components of a semiconductor device in accordance with some embodiments.

FIG. 17 is a schematic sectional view of transistors of a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

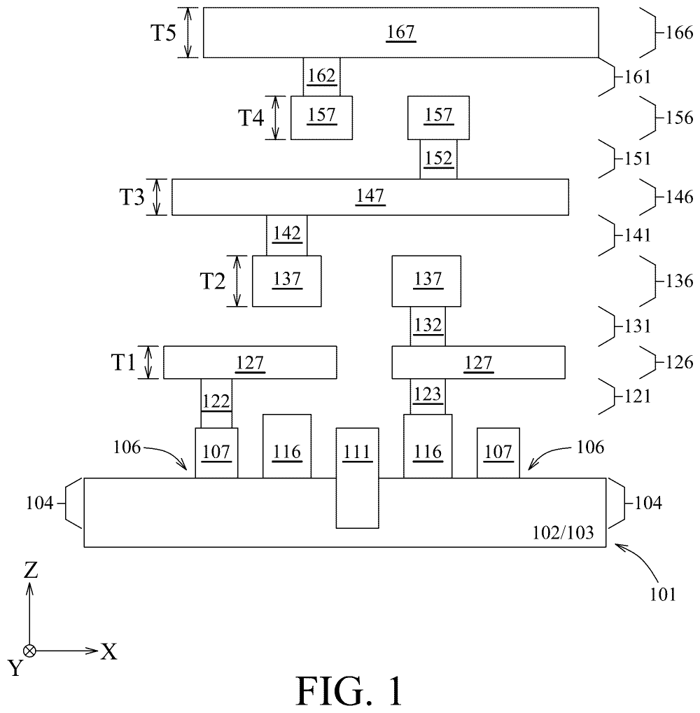

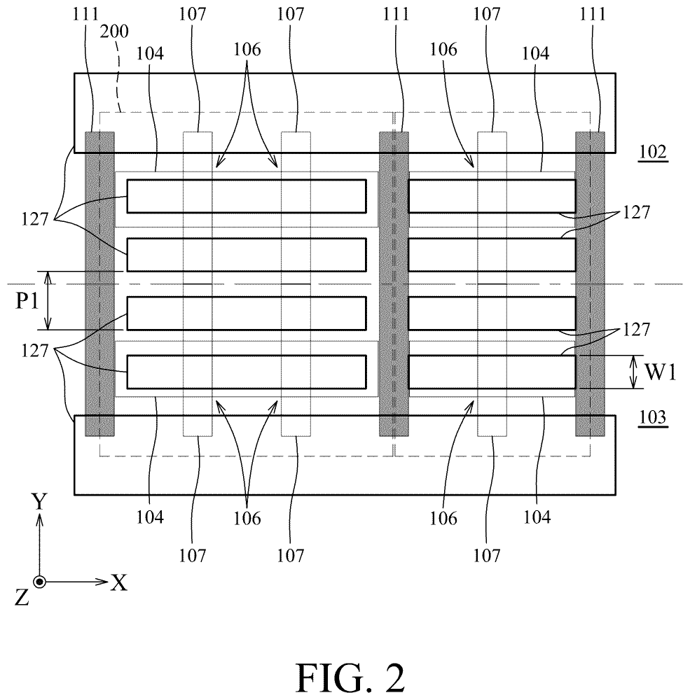

FIG. 1 is a schematic diagram illustrating relative positions (in a Z direction) of various components of a semiconductor device in accordance with some embodiments. FIGS. 2 to 4 are schematic diagrams illustrating relative positions (in an X direction and a Y direction) of various components of a semiconductor device in accordance with some embodiments. Referring to FIGS. 1 to 4, the semiconductor device includes a substrate 101, a plurality of transistors 106, a plurality of dielectric gates 111, a plurality of contacts 116, a bottom via layer 121, a first metal layer 126, a first via layer 131, a second metal layer 136, a second via layer 141, a third metal layer 146, a third via layer 151, a fourth metal layer 156, a fourth via layer 161 and a fifth metal layer 166.

The substrate 101 includes at least one p-type well 102, at least one n-type well 103 and a plurality of oxide diffusion regions 104. Each of the oxide diffusion regions 104 is disposed in one of the at least one p-type well 102 and the at least one n-type well 103, and extends in a first direction (e.g., an X direction transverse to a Z direction pointing from bottom to top of the semiconductor device). In some embodiments, the substrate 101 may be made of elemental semiconductor materials, such as crystalline silicon (Si), diamond, or germanium (Ge); compound semiconductor materials, such as gallium nitride (GaN), silicon carbide (SiC), gallium arsenide (GaAs), indium arsenide (InAs), or indium phosphide (InP); or alloy semiconductor materials, such as silicon germanium (SiGe), silicon germanium carbide, gallium arsenic phosphide (GaAsP), or gallium indium phosphide (GaInP). The material for forming the substrate 101 may be doped with p-type impurities or n-type impurities, or undoped. In addition, the substrate 101 may be a bulk silicon substrate, a silicon-on-insulator (SOI) substrate, or a germanium-on-insulator (GOI) substrate. Other suitable materials and/or configurations for the substrate 101 are within the contemplated scope of the present disclosure.

The transistors 106 are disposed on the substrate 101. Each of the transistors 106 has a gate electrode 107 and two source/drain regions (not shown), where the gate electrode 107 extends in a second direction (e.g., a Y direction transverse to the X direction and the Z direction) and intersects one of the oxide diffusion regions 104, and the source/drain regions are disposed in said one of the oxide diffusion regions 104 and at two opposite sides of the gate electrode 107 in the X direction. In some embodiments, each of the transistors 106 may be a planar field effect transistor (planar FET), a three-dimensional field effect transistor (3D FET) such as a fin field effect transistor (FinFET), a nanosheet gate-all-around field effect transistor (GAAFET), a nanowire GAAFET, or other suitable FETs.

Each of the dielectric gates 111 is disposed at least partially in the substrate 101, and extends in the Y direction. The dielectric gates 111 electrically isolate the oxide diffusion regions 104.

The contacts 116 are disposed on the substrate 101. Each of the contacts 116 is connected to one of the source/drain regions of the transistors 106. It should be noted that the contacts 116 are not depicted in FIGS. 2 to 4 for the sake of clarity.

The bottom via layer 121 is disposed over the transistors 106, the dielectric gates 111 and the contacts 116, and includes a plurality of gate vias 122 (only one of the gate vias 122 is depicted in FIG. 1), and a plurality of contact vias 123 (only one of the contact vias 123 is depicted in FIG. 1). It should be noted that the bottom via layer 121 is not depicted in FIGS. 2 to 4 for the sake of clarity.

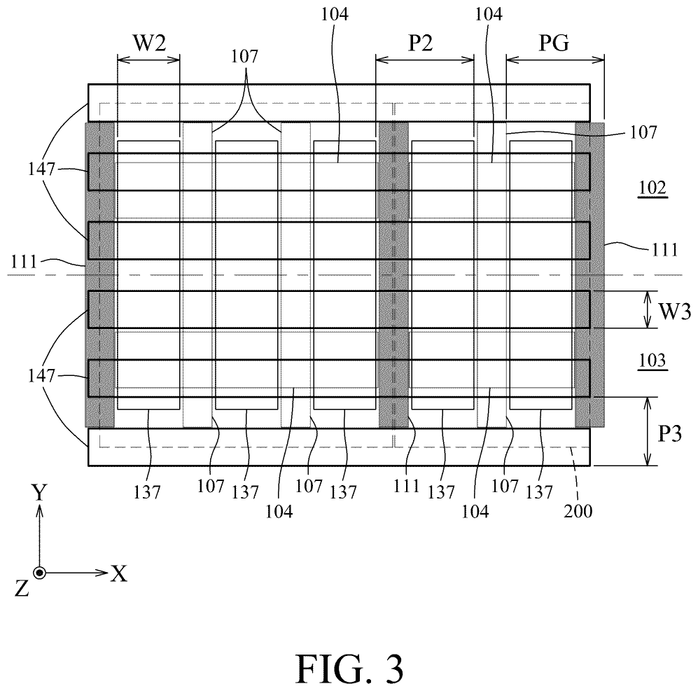

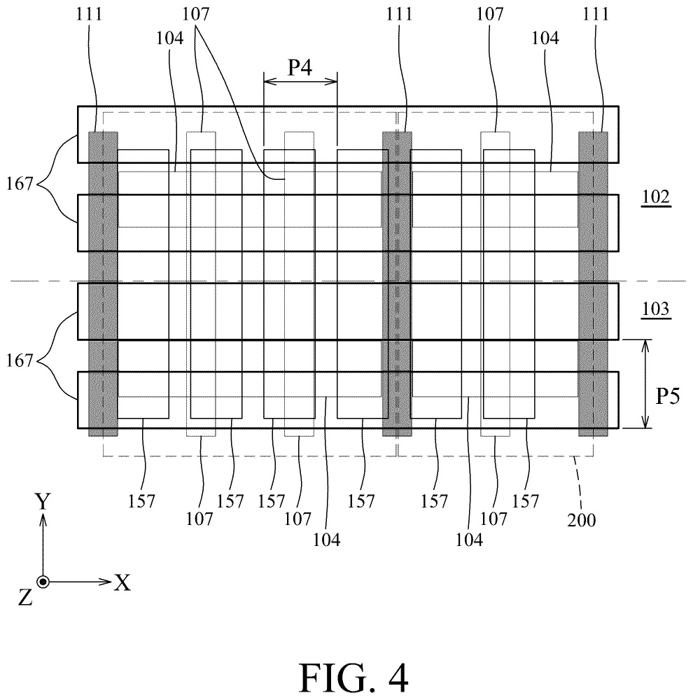

The first metal layer 126 is disposed over the bottom via layer 121, and includes a plurality of first metal lines 127. Each of the first metal lines 127 extends in the X direction, and has a thickness of T1 in the Z direction. It should be noted that the first metal layer 126 is not depicted in FIGS. 3 and 4 for the sake of clarity.

Each of the gate vias 122 interconnects one of the gate electrodes 107 of the transistors 106 and one of the first metal lines 127. Each of the contact vias 123 interconnects one of the source/drain regions of the transistors 106 and one of the first metal lines 127.

The first via layer 131 is disposed over the first metal layer 126, and includes a plurality of first vias 132 (only one of the first vias 132 is depicted in FIG. 1). It should be noted that the first via layer 131 is not depicted in FIGS. 2 to 4 for the sake of clarity.

The second metal layer 136 is disposed over the first via layer 131, and includes a plurality of second metal lines 137. Each of the second metal lines 137 extends in the Y direction, and has a thickness of T2 in the Z direction. It should be noted that the second metal layer 136 is not depicted in FIGS. 2 and 4 for the sake of clarity.

Each of the first vias 132 interconnects one of the first metal lines 127 and one of the second metal lines 137.

The second via layer 141 is disposed over the second metal layer 136, and includes a plurality of second vias 142 (only one of the second vias 142 is depicted in FIG. 1). It should be noted that the second via layer 141 is not depicted in FIGS. 2 to 4 for the sake of clarity.

The third metal layer 146 is disposed over the second via layer 141, and includes a plurality of third metal lines 147 (only one of the third metal lines 147 is depicted in FIG. 1). Each of the third metal lines 147 extends in the X direction, and has a thickness of T3 in the Z direction. It should be noted that the third metal layer 146 is not depicted in FIGS. 2 and 4 for the sake of clarity.

Each of the second vias 142 interconnects one of the second metal lines 137 and one of the third metal lines 147.

The third via layer 151 is disposed over the third metal layer 146, and includes a plurality of third vias 152 (only one of the third vias 152 is depicted in FIG. 1). It should be noted that the third via layer 151 is not depicted in FIGS. 2 to 4 for the sake of clarity.

The fourth metal layer 156 is disposed over the third via layer 151, and includes a plurality of fourth metal lines 157. Each of the fourth metal lines 157 extends in the Y direction, and has a thickness of T4 in the Z direction. It should be noted that the fourth metal layer 156 is not depicted in FIGS. 2 and 3 for the sake of clarity.

Each of the third vias 152 interconnects one of the third metal lines 147 and one of the fourth metal lines 157.

The fourth via layer 161 is disposed over the fourth metal layer 156, and includes a plurality of fourth vias 162 (only one of the fourth vias 162 is depicted in FIG. 1). It should be noted that the fourth via layer 161 is not depicted in FIGS. 2 to 4 for the sake of clarity.

The fifth metal layer 166 is disposed over the fourth via layer 161, and includes a plurality of fifth metal lines 167 (only one of the fifth metal lines 167 is depicted in FIG. 1). Each of the fifth metal lines 167 extends in the X direction, and has a thickness of T5 in the Z direction. It should be noted that the fifth metal layer 166 is not depicted in FIGS. 2 and 3 for the sake of clarity.

Each of the fourth vias 162 interconnects one of the fourth metal lines 157 and one of the fifth metal lines 167.

The transistors 106 are connected to the contacts 116, the bottom via layer 121, the first metal layer 126, the first via layer 131, the second metal layer 136, the second via layer 141, the third metal layer 146, the third via layer 151, the fourth metal layer 156, the fourth via layer 161 and the fifth metal layer 166 in a predetermined way, so as to form a plurality standard cells 200 which may be inverters, NAND gates, NOR gates, AND gates, OR gates, flip-flops, other suitable specific functional circuits, or combinations thereof.

In some embodiments, T2 may be greater than any one of T1, T3, T4 and T5 (i.e., the second metal lines 137 may be thicker than the first metal lines 127, the third metal lines 147, the fourth metal lines 157 and the fifth metal lines 167). Therefore, routing traces of the semiconductor device that should have low trace resistances may be implemented using the second metal lines 137, thereby enhancing performance of the semiconductor device. Moreover, the second metal lines 137 can be wide and short, thereby reducing parasitic capacitances related to the second metal lines 137 and further enhancing the performance of the semiconductor device. In addition, a ratio of T2 to T1 may fall within a range of from about 1.2 to about 3, and a ratio of T2 to T3 may fall within a range of from about 1.2 to about 3. The term “about,” when used with a value, can encompass a deviation of ±5% from the specified amount. For example, T2>T5>T4>T3>T1, T2/T5=1.05, T2/T4=1.1, T2/T3=1.2, and T2/T1=1.4.

In some embodiments, T2 may be greater than any one of T1 and T3 (i.e., the second metal lines 137 are thicker than the first metal lines 127 and the third metal lines 147), and T4 may be greater than any one of T3 and T5 (i.e., the fourth metal lines 157 are thicker than the third metal lines 147 and the fifth metal lines 167). Therefore, the routing traces of the semiconductor device that should have low trace resistances may be implemented using the second metal lines 137 and the fourth metal lines 157, thereby enhancing the performance of the semiconductor device. Moreover, the second metal lines 137 and the fourth metal lines 157 can be wide and short, thereby reducing parasitic capacitances related to the second metal lines 137 and the fourth metal lines 157 and further enhancing the performance of the semiconductor device. In addition, a ratio of T2 to T1 may fall within a range of from about 1.2 to about 3, and a ratio of T2 to T3 may fall within a range of from about 1.2 to about 3. For example, T2>T3>T1, T4>T5>T3, T2/T3=1.2, T2/T1=1.4, T4/T5=1.05, and T4/T3=1.2.

The gate electrodes 107 of the transistors 106 and the dielectric gates 111 have a minimum pitch of PG. The first metal lines 127 have a minimum pitch of P1. The second metal lines 137 have a minimum pitch of P2. The third metal lines 147 have a minimum pitch of P3. The fourth metal lines 157 have a minimum pitch of P4. The fifth metal lines 167 have a minimum pitch of P5. A pitch of components is defined as a dimension between two adjacent components (measured from the same locations, such as center to center, or left edge to left edge). The pitch may not be a constant, so the minimum pitch is defined and constrained in the semiconductor device.

In some embodiments, a ratio of P2 to PG may be equal to about 1 (i.e., the minimum pitch of the second metal lines 137 may be substantially equal to the minimum pitch of the gate electrodes 107 of the transistors 106 and the dielectric gates 111), so the thickness of the second metal lines 137 and a width of each of the second metal lines 137 can be made larger, and line and routing utilization of the second metal layer 136 can be enhanced.

In some embodiments, a ratio of P4 to PG may be equal to about ¾ or about 1, so the thickness of the fourth metal lines 157 and a width of each of the fourth metal lines 157 can be made larger, and line and routing utilization of the fourth metal layer 156 can be enhanced.

In some embodiments, P2 may be greater than P5, P5 may be greater than P4, P4 may be greater than P3, P3 may be greater than P1, and each of P2/P5, P5/P4, P4/P3 and P3/P1 may fall within a range of from about 1.05 to about 2, so routing traces of the semiconductor device, trace resistances of which do not matter, may be implemented using the first metal lines 127 and the third metal lines 147, thereby enhancing density of the semiconductor device.

In some embodiments, P2 may be greater than P4, P4 may be greater than P5, P5 may be greater than P3, P3 may be greater than P1, and each of P2/P4, P4/P5, P5/P3 and P3/P1 may fall within a range of from about 1.05 to about 2, so the routing traces of the semiconductor device, the trace resistances of which do not matter, may be implemented using the first metal lines 127 and the third metal lines 147, thereby enhancing the density of the semiconductor device.

In some embodiments, P2 may be greater than P3, P3 may be greater than P1, P4 may be greater than P5, and P5 may be greater than P3, so the routing traces of the semiconductor device may be implemented using the first metal lines 127 and the third metal lines 147 when the trace resistance does not matter, thereby enhancing the density of the semiconductor device.

In some embodiments, each of PG and P2 may fall within a range of from about 36 nm to about 52 nm, P1 may fall within a range of from about 15 nm to about 26 nm; P3 may fall within a range of from about 22 nm to about 32 nm, P4 may fall within a range of from about 32 nm to about 52 nm, and P5 may fall within a range of from about 35 nm to about 44 nm.

In some embodiments, each of PG and P2 may fall within a range of from about 36 nm to about 52 nm, P1 may fall within a range of from about 18 nm to about 26 nm; P3 may fall within a range of from about 22 nm to about 32 nm, P4 may fall within a range of from about 36 nm to about 52 nm, and P5 may fall within a range of from about 35 nm to about 44 nm.

The first metal lines 127 have a minimum width of W1. The second metal lines 137 have a minimum width of W2. The third metal lines 147 have a minimum width of W3. In some embodiments, W2 is greater than any one of W1 and W3, and each of W2/W1 and W2/W3 may fall within a range of from about 1.2 to about 3.

In some embodiments, the contacts 116 may be made of cobalt, titanium, titanium nitride, tungsten, other suitable materials, or combinations thereof. In some embodiments, the vias 122, 123, 132, 142, 152, 162 and the metal lines 127, 137, 147, 157, 167 may be made of titanium, titanium nitride, tantalum nitride, cobalt, ruthenium, platinum, tungsten, aluminum, copper, other suitable materials, or combinations thereof. In some embodiments, the source/drain regions of the transistors 106 that are n-type may be epitaxially formed using a material such as silicon phosphide, silicon carbide, silicon phosphoric carbide, silicon arsenide, silicon, other suitable materials, or combinations thereof. In some embodiments, the source/drain regions of the transistors 106 that are p-type may be epitaxially formed using a material such as silicon germanium doped with boron, silicon germanium doped with boron and carbon, other suitable materials, or combinations thereof. In some embodiments, the gate electrodes 107 of the transistors 106 may be made of a work function metal such as titanium nitride, tantalum nitride, titanium aluminide, titanium aluminum nitride, tantalum aluminide, tantalum aluminum nitride, tantalum aluminum carbide, tantalum carbonitride, tungsten nitrogen carbide, cobalt, nickel, platinum, tungsten, other suitable materials, or combinations thereof. The gate electrodes of the transistors 106 that are n-type and the gate electrodes of the transistors 106 that are p-type may be made of the same material, or may be made of different materials.

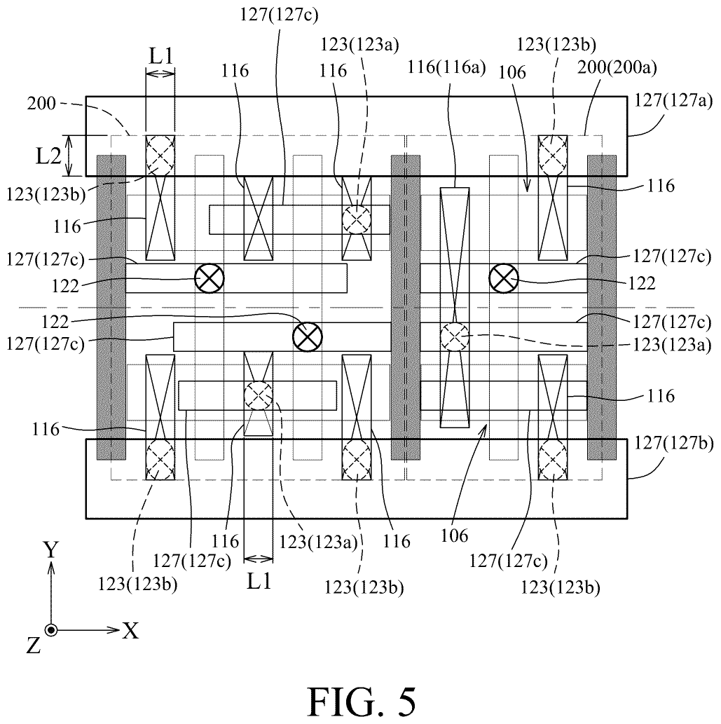

FIGS. 5 to 7 are schematic diagrams illustrating relative positions (in the X direction and the Y direction) of various components of a semiconductor device in accordance with some embodiments. It should be noted that each of FIGS. 5 to 7 omits the depiction of some components of the semiconductor device for the sake of clarity.

In some embodiments, as shown in FIG. 5, the contact vias 123 may include a plurality of first contact vias (123a) and a plurality of second contact vias (123b). The first metal lines 127 may include a first metal line (127a) that is for transmission of a ground voltage, a first metal line (127b) that is for transmission of a supply voltage, and a plurality of first metal lines (127c) that are not for transmission of either the ground voltage or the supply voltage. Each of the first contact vias (123a) may be connected to one of the first metal lines (127c), and may have a top area of A1. Each of the second contact vias (123b) may be connected to one of the first metal lines (127a, 127b), and may have a top area of A2. A2/A1 may fall within a range of from about 1.2 to about 5. When A2/A1 is greater than about 5, each of the second contact vias (123b) may occupy an undesirably large area. When A2/A1 is smaller than about 1.2, each of the second contact vias (123b) may not have a sufficiently small contact resistance. In some embodiments, each of the first contact vias (123a) may be square or circular, and may have a side length or a diameter of L1; and each of the second contact vias (123b) may be rectangular or oval, may extend in the Y direction, and may have a length (in the Y direction) of L2 and a width (in the X direction) of L1, where L2/L1 may fall within a range of from about 1.2 to about 5.

In some embodiments, as shown in FIG. 5, with respect to each of the standard cells 200, when the standard cell 200 is an inverter (200a) that includes two transistors 106, a source/drain region of one of the two transistors 106 and a source/drain region of the other one of the two transistors 106 may be interconnected by the same contact (116a).

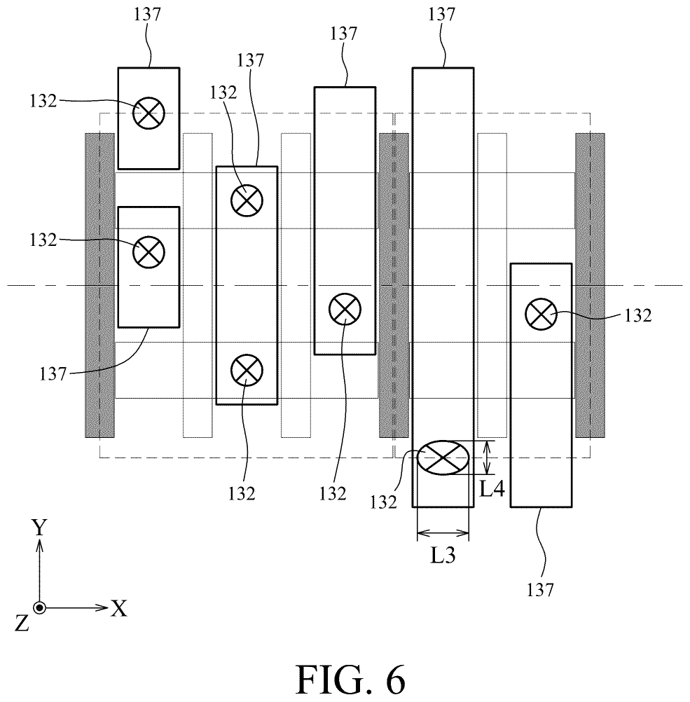

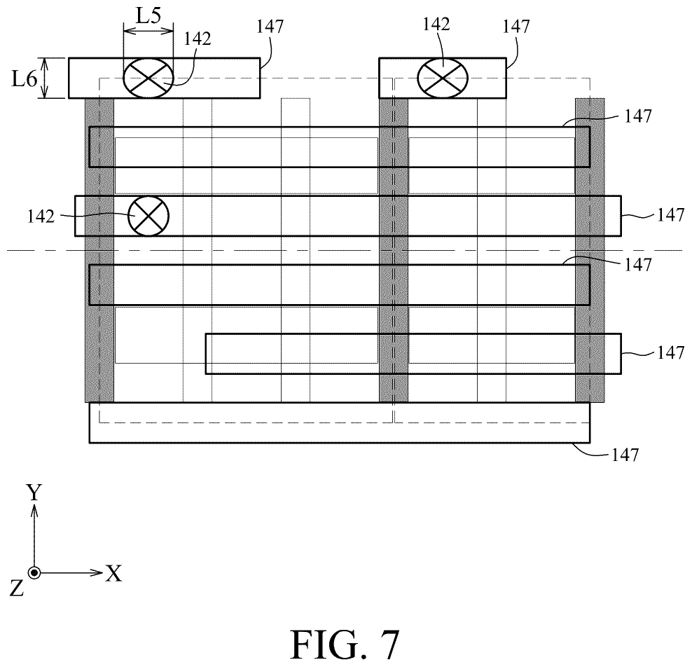

In some embodiments, as shown in FIG. 6, with respect to each of the first vias 132, when the first via 132 should have a low contact resistance, the first via 132 may be rectangular or oval, rather than square or circular, may be parallel to the first metal lines 127 (i.e., extending in the X direction), and may have a length (in the X direction) of L3 and a width (in the Y direction) of L4, where L3/L4 may fall within a range of from about 1.1 to about 3. When L3/L4 is greater than about 3, the first via 132 may occupy an undesirably large area. When L3/L4 is smaller than about 1.1, each of the first via 132 may not have a sufficiently small contact resistance. Similarly, as shown in FIG. 7, with respect to each of the second vias 142, when the second via 142 should have a low contact resistance, the second via 142 may be rectangular or oval, rather than square or circular, may be parallel to the third metal lines 147 (i.e., extending in the X direction), and may have a length (in the X direction) of L5 and a width (in the Y direction) of L6, where L5/L6 may fall within a range of from about 1.1 to about 3. When L5/L6 is greater than about 3, the second via 142 may occupy an undesirably large area. When L3/L4 is smaller than about 1.1, a contact resistance of each of the second via 142 may not be sufficiently small.

Referring to FIGS. 5 to 7, in some embodiments where the minimum width of the second metal lines 137 is greater than the minimum width of the first metal lines 127, with respect to each of the first vias 132, a center of the first via 132 may not be aligned with a center of an intersection of the first metal line 127 and the second metal line 137 that are connected to the first via 132, so that a spacing between the first via 132 and another one of the first vias 132 may be increased. Similarly, in some embodiments where the minimum width of the second metal lines 137 is greater than the minimum width of the third metal lines 147, with respect to each of the second vias 142, a center of the second via 142 may not be aligned with a center of an intersection of the second metal line 137 and the third metal line 147 that are connected to the second via 142, so that a spacing between the second vias 142 and another one of the second vias 142 may be increased.

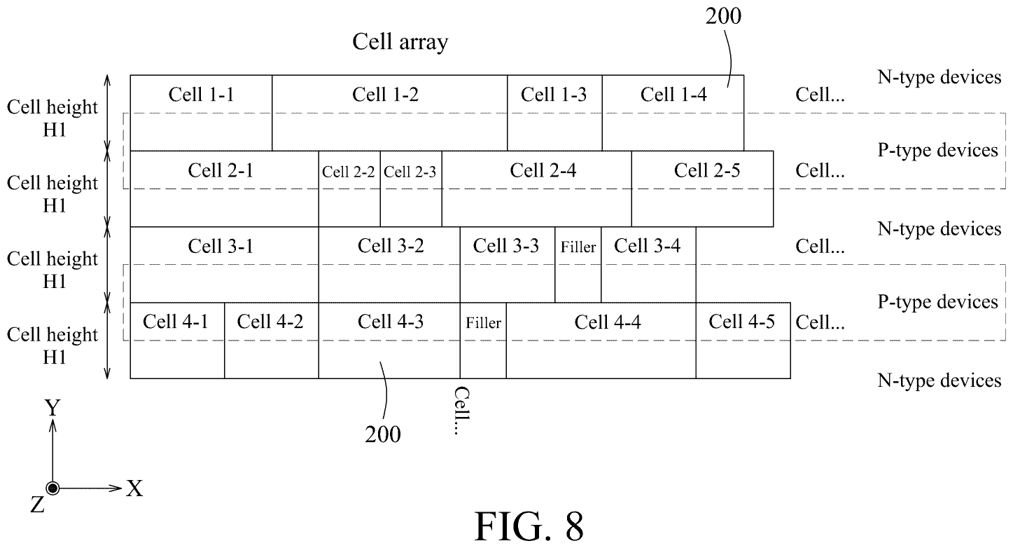

FIG. 8 is a schematic diagram illustrating arrangement of standard cells of a semiconductor device in accordance with some embodiments. In some embodiments, the standard cells 200 may be arranged in a plurality of rows extending in the X direction, and may have the same cell height of H1 in the Y direction. This can facilitate layout automation of the semiconductor device.

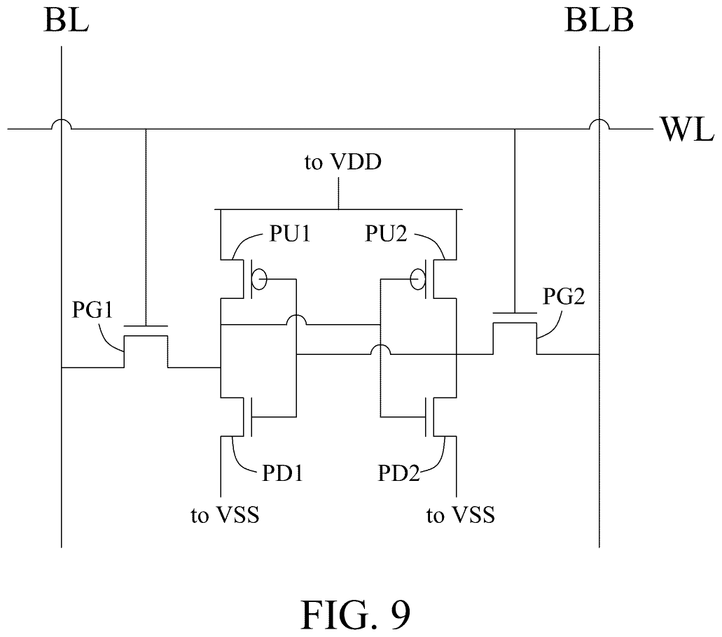

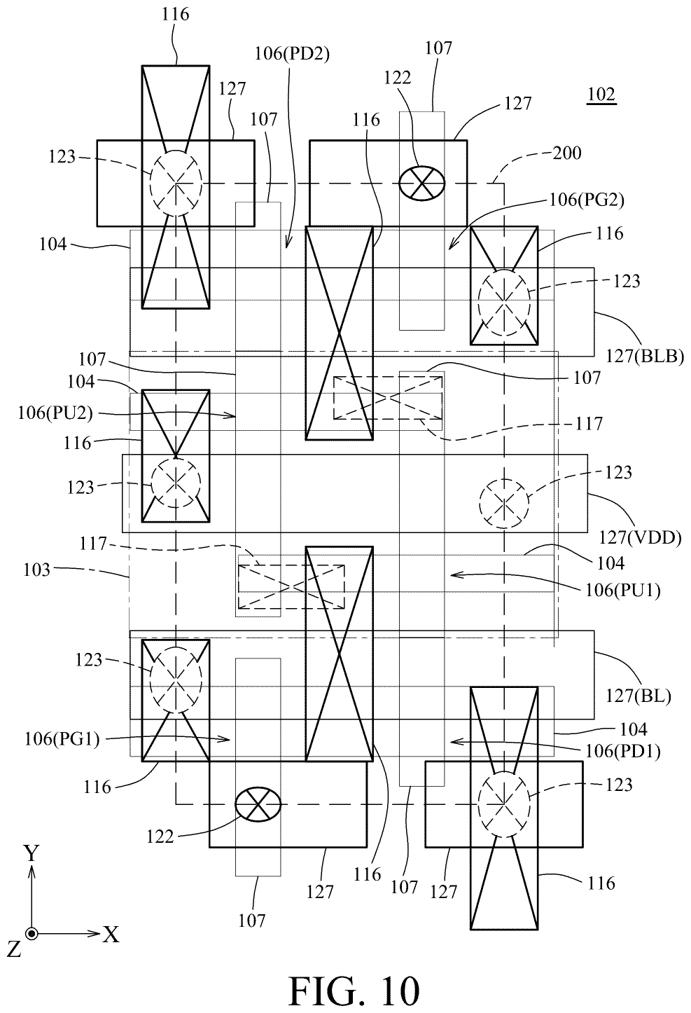

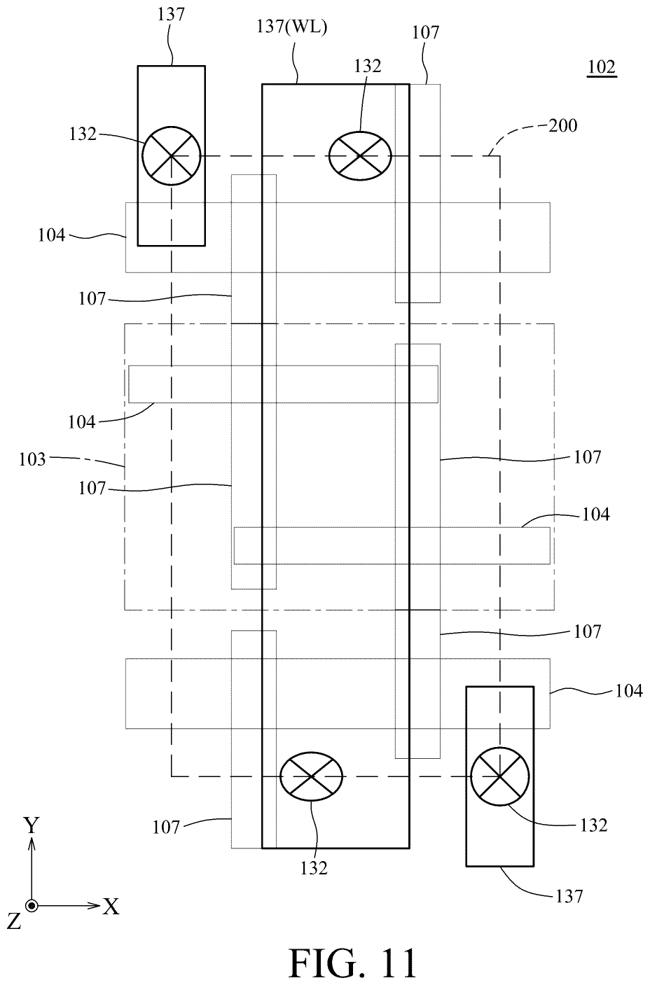

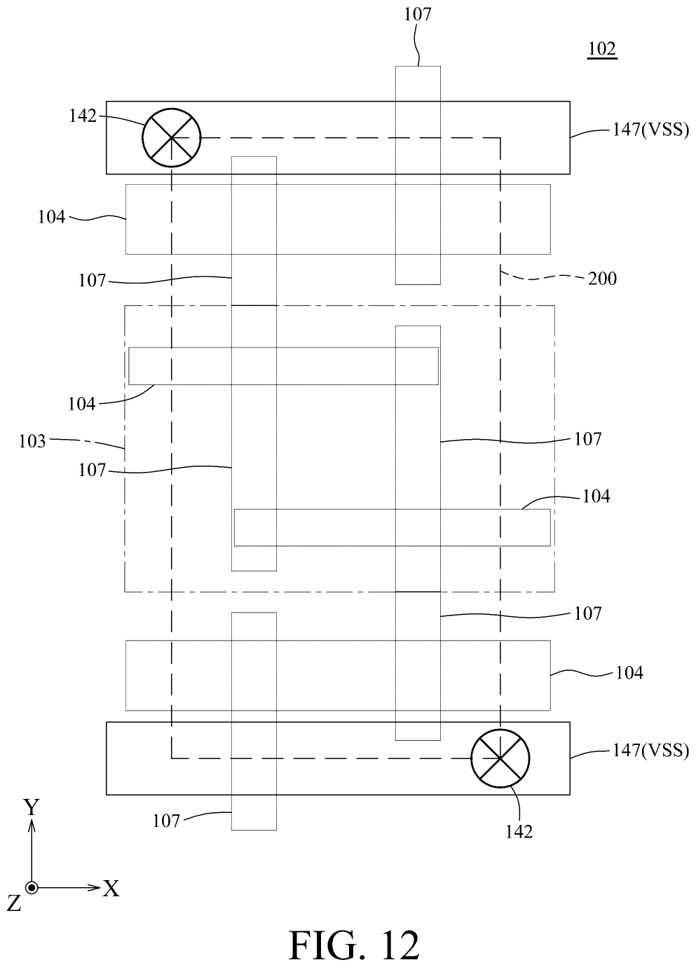

FIG. 9 is a circuit diagram illustrating a static random access memory (SRAM) cell in accordance with some embodiments. FIGS. 10 to 12 are schematic diagrams illustrating relative positions (in the X direction and the Y direction) of various components of an SRAM cell in accordance with some embodiments. It should be noted that each of FIGS. 10 to 12 omits the depiction of some components of the SRAM cell for the sake of clarity. Referring to FIGS. 9 to 12, in some embodiments, the semiconductor device may be an SRAM device, and each of the standard cells 200 may be an SRAM cell. It should be noted that only one of the SRAM cells 200 is depicted in FIGS. 10 to 12. Each of the SRAM cells 200 may include six transistors 106 (including two p-type transistors (PU1, PU2) and four n-type transistors (PD1, PD2, PG1, PG2) as shown in FIG. 9). The SRAM device may further include a plurality of contacts 117. Some of the first metal lines 127 may serve as non-inverting bit lines (BL). Others of the first metal lines 127 may serve as inverting bit lines (BLB). Yet some others of the first metal lines 127 may serve as supply lines (VDD) that are for transmission of the supply voltage. Some of the second metal lines 137 may serve as word lines (WL). Some of the third power lines 147 may serve as ground lines (VSS) that are for transmission of the ground voltage. As shown in FIG. 10, each of the contacts 117 may interconnect one of the gate electrodes 107 and one of the contacts 116. As shown in FIG. 10, with respect to each of the SRAM cells 200, one of the source/drain regions of the transistor (PG1) may be connected to one of the non-inverting bit lines (BL), one of the source/drain regions of the transistor (PG2) may be connected to one of the inverting bit lines (BLB), and one of the source/drain regions of the transistor (PU1) and one of the source/drain regions of the transistor (PU2) may be connected to the same one of the supply lines (VDD). As shown in FIGS. 10 and 11, the gate electrodes 107 of the transistors (PG1, PG2) may be connected to the same one of the word lines (WL). As shown in FIGS. 10 to 12, one of the source/drain regions of the transistor (PD1) and one of the source/drain regions of the transistor (PD2) may be respectively connected to two different ones of the ground lines (VSS). Since the word lines (WL) are implemented using the second metal lines 127 which have the greatest thickness among the first to fifth metal lines 127, 137, 147, 157, 167, a line resistance of each of the word lines (WL) can be small.

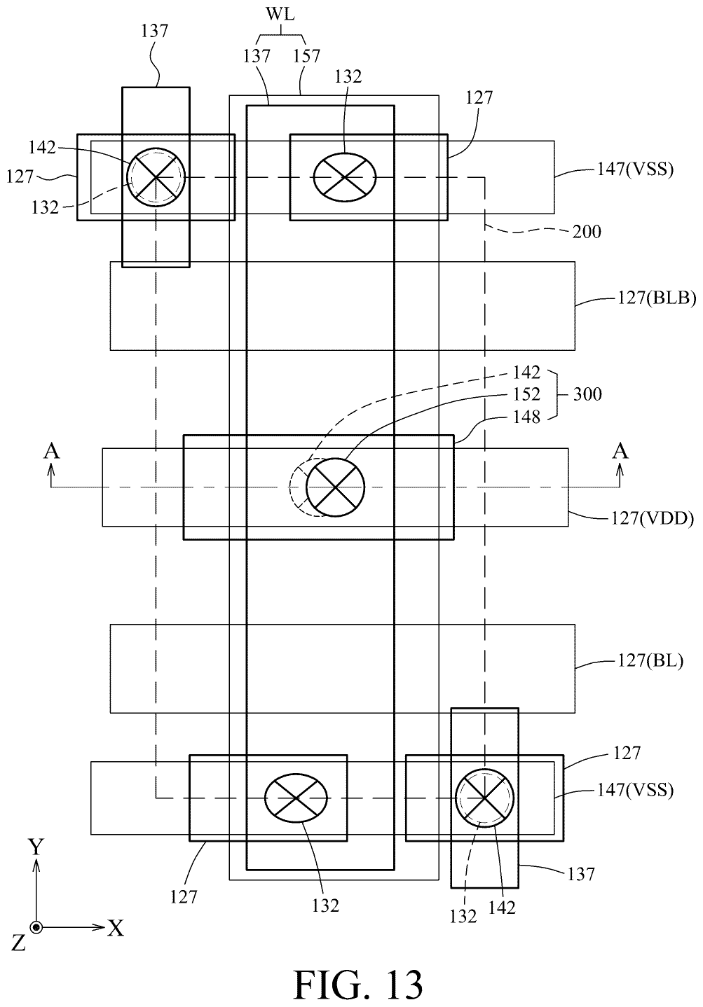

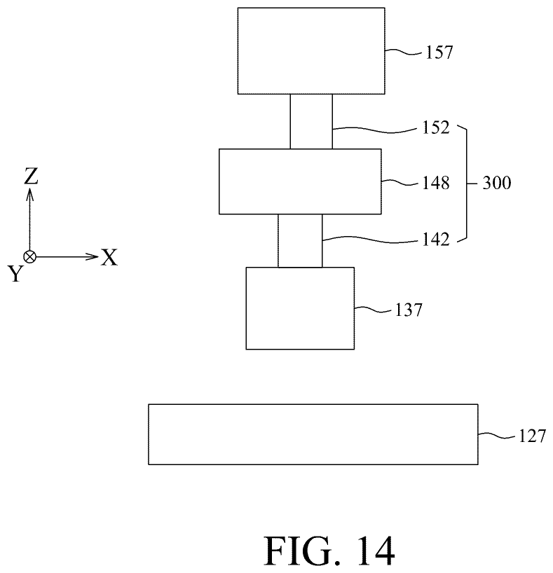

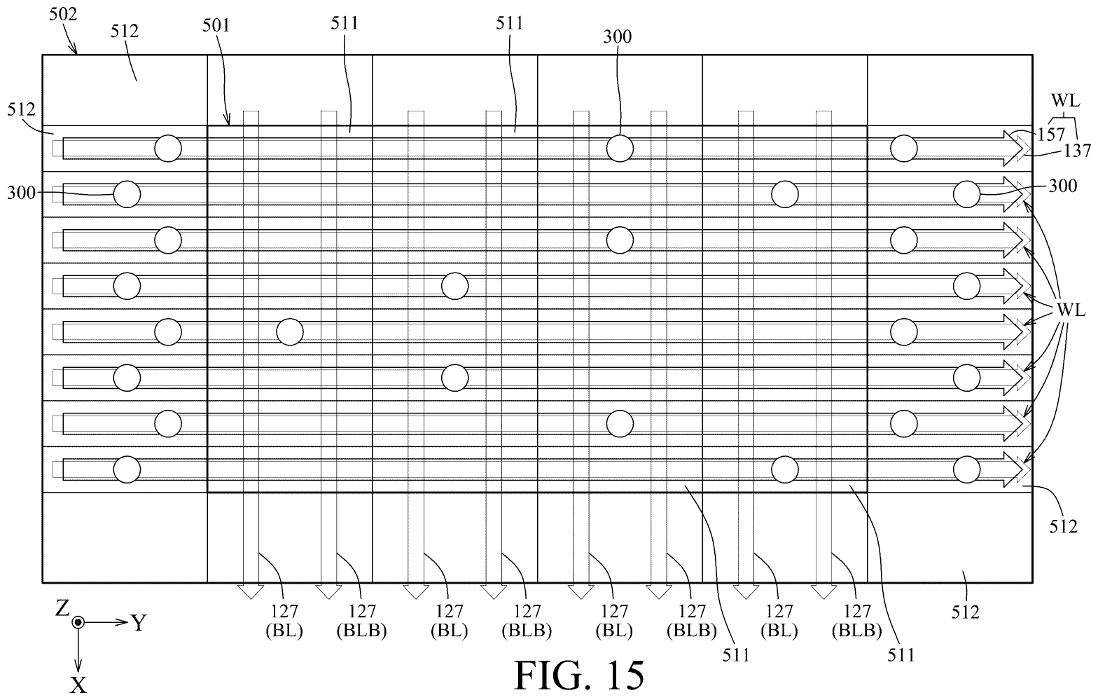

FIG. 13 is a schematic diagram illustrating relative positions (in the X direction and the Y direction) of some components of an SRAM cell in accordance with some embodiments. FIG. 14 is a schematic sectional view of the SRAM cell taken along line A-A of FIG. 13 in accordance with some embodiments. FIG. 15 is a schematic diagram illustrating relative positions (in the X direction and the Y direction) of some components of an SRAM device in accordance with some embodiments. Referring to FIGS. 13 to 15, in some embodiments, some of the second metal lines 137 and some of the fourth metal lines 157 may cooperatively serve as word lines (WL) each including a second metal line 137 and a fourth metal line 157. As shown in FIG. 15, the SRAM device may include a plurality of storage cells 511 and a plurality of dummy cells 512. Each of the storage cells 511 may have a circuit as shown in FIG. 9. The storage cells 511 may be disposed in an inner region 501, and the dummy cells 512 may be disposed in an outer region 502 surrounding the inner region 501. With respect to each of the word lines (WL), the second metal line 137 and the fourth metal line 157 may be connected to each other through at least three interconnect elements 300, where two of the interconnect elements 300 may be disposed in the outer region 502 and respectively at two opposite sides of the inner region 501 in the Y direction, and the other one(s) of the interconnect elements 300 may be disposed in the inner region 501. As shown in FIGS. 13 and 14, each of the interconnect elements 300 may include a second via 142, a landing pad 148 and a third via 152, where the landing pad 148 may be configured in the third metal layer 146 (see FIG. 1), and may interconnect the second via 142 and the third via 152. As such, the line resistances of the word lines (WL) can be reduced.

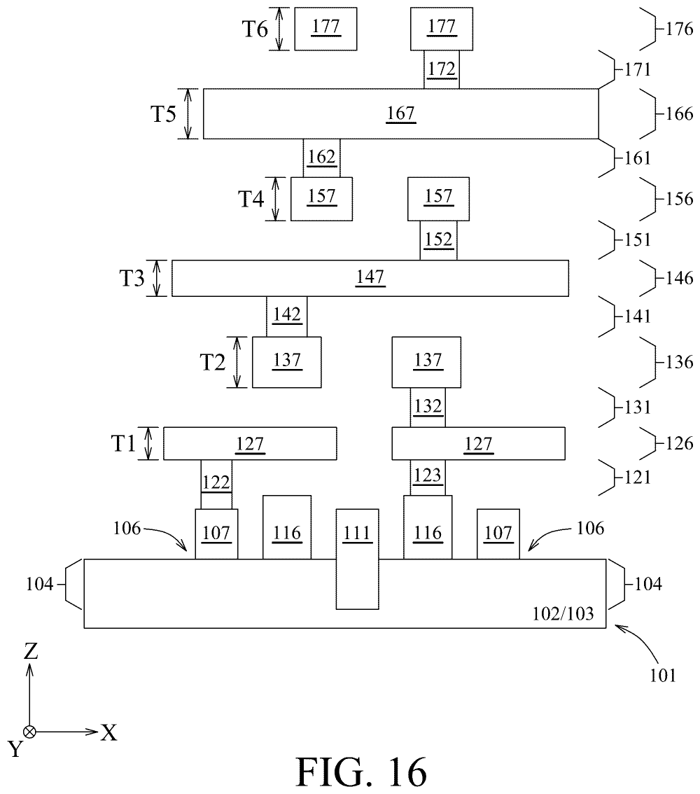

FIG. 16 is a schematic diagram illustrating relative positions (in the Z direction) of various components of a semiconductor device in accordance with some embodiments. Referring to FIG. 16, the semiconductor device depicted in FIG. 16 is similar to the semiconductor device depicted in FIG. 1, but differs from the semiconductor device depicted in FIG. 1 in that the semiconductor device depicted in FIG. 16 further includes a fifth via layer 171 and a sixth metal layer 176.

In the semiconductor device depicted in FIG. 16, the fifth via layer 171 is disposed over the fifth metal layer 166, and includes a plurality of fifth vias 172 (only one of the fifth vias 172 is depicted in FIG. 16). The sixth metal layer 176 is disposed over the fifth via layer 171, and includes a plurality of sixth metal lines 177. Each of the sixth metal lines 177 extends in the Y direction, and has a thickness of T6 in the Z direction. Each of the fifth vias 172 interconnects one of the fifth metal lines 167 and one of the sixth metal lines 177. In some embodiments, T6 may be smaller than T2.

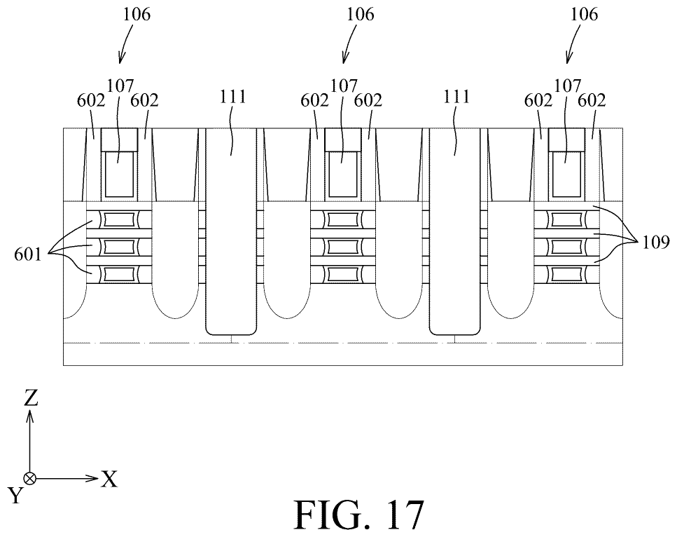

FIG. 17 is a schematic sectional view of transistors of a semiconductor device in accordance with some embodiments. In some embodiments, each of the transistors 106 may be a nanosheet GAAFET as shown in FIG. 17. With respect to each of the transistors 106, the transistor 106 further includes a plurality of channel layers 109, and a total number of the channel layers 109 falls within a range of from 2 to 10. FIG. 17 depicts an example where the transistor 106 includes three channel layers 109. Each of the channel layers 109 has a thickness (in the Z direction) that may fall within a range of from about 3 nm to about 8 nm. A spacing of two adjacent ones of the channel layers 109 may fall within a range of from about 4 nm to about 15 nm. The transistor 106 further includes a plurality of inner spacers 601 and a plurality of top spacers 602. Each of the inner spacers 601 has a thickness (in the X direction) that may fall within a range of from about 2 nm to about 10 nm. Each of the top spacers 601 has a thickness (in the X direction) that may fall within a range of from about 3 nm to about 12 nm. The inner spacers 601 have an effective dielectric constant that may be higher than an effective dielectric constant of the top spacers 602. The inner spacers 601 may be made of silicon oxide, silicon nitride, silicon oxynitride, silicon oxycarbide, silicon oxycarbonitride, other suitable dielectric materials, air gaps, or combinations thereof. The top spacers 602 may be made of silicon oxide, silicon nitride, carbon doped oxide, nitrogen doped oxide, porous oxide, other suitable dielectric materials, air gaps, or combinations thereof.

In accordance with some embodiments of the present disclosure, a semiconductor device includes a substrate, a plurality of transistors, a first metal layer, a second metal layer and a third metal layer. The transistors are disposed on the substrate, and each include a gate electrode that extends in a first direction. The first metal layer is disposed over the transistors, and includes a plurality of first metal lines, where each of the first metal lines extends in a second direction transverse to the first direction, and has a thickness of T1. The second metal layer is disposed over the first metal layer, and includes a plurality of second metal lines, where each of the second metal lines extends in the first direction, and has a thickness of T2. The third metal layer is disposed over the second metal layer, and includes a plurality of third metal lines, where each of the third metal lines extends in the second direction, and has a thickness of T3. One of T2/T1 and T2/T3 is greater than or equal to 1.2.

In accordance with some embodiments of the present disclosure, the gate electrodes of the transistors have a minimum pitch of PG, the second metal lines have a minimum pitch of P2, and P2 is substantially equal to PG.

In accordance with some embodiments of the present disclosure, the semiconductor device further includes a via layer. The via layer is disposed between the third metal layer and the second metal layer, and includes a plurality of vias. Each of the vias has an elongated shape oriented in the second direction, and has a length of L2 in the second direction and a width of W2 in the first direction. 1.1≤L2/W2≤3.

In accordance with some embodiments of the present disclosure, the semiconductor device further includes a fourth metal layer and a fifth metal layer. The fourth metal layer is disposed over the third metal layer, and includes a plurality of fourth metal lines, where each of the fourth metal lines extends in the first direction, and has a thickness of T4. The fifth metal layer is disposed over the fourth metal layer, and includes a plurality of fifth metal lines, where each of the fifth metal lines extends in the second direction, and has a thickness of T5. T2 is greater than any one of T1, T3, T4 and T5.

In accordance with some embodiments of the present disclosure, the semiconductor device further includes a sixth metal layer. The sixth metal layer is disposed over the fifth metal layer, and includes a plurality of sixth metal lines, where each of the sixth metal lines extends in the first direction, and has a thickness of T6. T6<T2.

In accordance with some embodiments of the present disclosure, the semiconductor device further includes a bottom via layer. The bottom via layer is disposed over the transistors and below the first metal layer, and includes a plurality of first contact vias and a plurality of second contact vias. Each of the first contact vias is connected to one of the first metal lines, the second metal lines, the third metal lines, the fourth metal lines and the fifth metal lines that is not for transmission of either a supply voltage or a ground voltage, and has a top area of A1. Each of the second contact vias is connected to one of the first metal lines, the second metal lines, the third metal lines, the fourth metal lines and the fifth metal lines that is for transmission of one of the supply voltage and the ground voltage, and has a top area of A2. 1.2≤A2/A1≤5.

In accordance with some embodiments of the present disclosure, the first metal lines have a minimum pitch of P1, the second metal lines have a minimum pitch of P2, the third metal lines have a minimum pitch of P3, the fourth metal lines have a minimum pitch of P4, the fifth metal lines have a minimum pitch of P5, P2>P5>P4>P3>P1, and each of T2/T5, T5/T4, T4/T3 and T3/T1 falls within a range of from 1.05 to 2.

In accordance with some embodiments of the present disclosure, the first metal lines have a minimum pitch of P1, the second metal lines have a minimum pitch of P2, the third metal lines have a minimum pitch of P3, the fourth metal lines have a minimum pitch of P4, the fifth metal lines have a minimum pitch of P5, P2>P4>P5>P3>P1, and each of T2/T4, T4/T5, T5/T3 and T3/T1 falls within a range of from 1.05 to 2.

In accordance with some embodiments of the present disclosure, the gate electrodes of the transistors have a minimum pitch of PG, the fourth metal lines have a minimum pitch of P4, and P4 is substantially equal to three-fourths of PG.

In accordance with some embodiments of the present disclosure, the gate electrodes of the transistors have a minimum pitch of PG that falls within a range of from 36 nm to 52 nm, the first metal lines have a minimum pitch of P1 that falls within a range of from 15 nm to 26 nm, the second metal lines have a minimum pitch of P2 that falls within a range of from 36 nm to 52 nm, the third metal lines have a minimum pitch of P3 that falls within a range of from 22 nm to 32 nm, the fourth metal lines have a minimum pitch of P4 that falls within a range of from 32 nm to 52 nm, and the fifth metal lines have a minimum pitch of P5 that falls within a range of from 35 nm to 44 nm.

In accordance with some embodiments of the present disclosure, a semiconductor device includes a substrate, a plurality of transistors, a first metal layer, a second metal layer and a third metal layer. The transistors are disposed on the substrate, and each include a gate electrode that extends in a first direction. The first metal layer is disposed over the transistors, and includes a plurality of first metal lines, where each of the first metal lines extends in a second direction transverse to the first direction, and the first metal lines have a minimum width of W1. The second metal layer is disposed over the first metal layer, and includes a plurality of second metal lines, where each of the second metal lines extends in the first direction, and the second metal lines have a minimum width of W2. The third metal layer is disposed over the second metal layer, and includes a plurality of third metal lines, where each of the third metal lines extends in the second direction, and the third metal lines have a minimum width of W3. Each of W2/W1 and W2/W3 is greater than or equal to 1.2.

In accordance with some embodiments of the present disclosure, the gate electrodes of the transistors have a minimum pitch of PG, the second metal lines have a minimum pitch of P2, and P2 is substantially equal to PG.

In accordance with some embodiments of the present disclosure, the semiconductor device further includes a fourth metal layer and a fifth metal layer. The fourth metal layer is disposed over the third metal layer, and includes a plurality of fourth metal lines, where each of the fourth metal lines extends in the first direction, and has a thickness of T4. The fifth metal layer is disposed over the fourth metal layer, and includes a plurality of fifth metal lines, where each of the fifth metal lines extends in the second direction, and has a thickness of T5. Each of the first metal lines has a thickness of T1. Each of the second metal lines has a thickness of T2. Each of the third metal lines has a thickness of T3. T2 is greater than any one of T1 and T3, and T4 is greater than any one of T3 and T5.

In accordance with some embodiments of the present disclosure, the gate electrodes of the transistors have a minimum pitch of PG, the fourth metal lines have a minimum pitch of P4, and P4 is substantially equal to three-fourths of PG.

In accordance with some embodiments of the present disclosure, the gate electrodes of the transistors have a minimum pitch of PG, the fourth metal lines have a minimum pitch of P4, and P4 is substantially equal to PG.

In accordance with some embodiments of the present disclosure, the gate electrodes of the transistors have a minimum pitch of PG that falls within a range of from 36 nm to 52 nm, the first metal lines have a minimum pitch of P1 that falls within a range of from 18 nm to 26 nm, the second metal lines have a minimum pitch of P2 that falls within a range of from 36 nm to 52 nm, the third metal lines have a minimum pitch of P3 that falls within a range of from 22 nm to 32 nm, the fourth metal lines have a minimum pitch of P4 that falls within a range of from 36 nm to 52 nm, and the fifth metal lines have a minimum pitch of P5 that falls within a range of from 35 nm to 44 nm.

In accordance with some embodiments of the present disclosure, a semiconductor device includes a substrate, a static random access memory (SRAM) cell, a first metal layer, a second metal layer, a third metal layer, a fourth metal layer and a fifth metal layer. The SRAM cell is disposed on the substrate, and includes a plurality of transistors, where each of the transistors includes a gate electrode that extends in a first direction. The first metal layer is disposed over the SRAM cell, and includes a plurality of first metal lines, where each of the first metal lines extends in a second direction transverse to the first direction, and has a thickness of T1. The second metal layer is disposed over the first metal layer, and includes a plurality of second metal lines, where each of the second metal lines extends in the first direction, and has a thickness of T2. The third metal layer is disposed over the second metal layer, and includes a plurality of third metal lines, where each of the third metal lines extends in the second direction, and has a thickness of T3. The fourth metal layer is disposed over the third metal layer, and includes a plurality of fourth metal lines, where each of the fourth metal lines extends in the first direction, and has a thickness of T4. The fifth metal layer is disposed over the fourth metal layer, and includes a plurality of fifth metal lines, where each of the fifth metal lines extends in the second direction, and has a thickness of T5. T2 is greater than any one of T1 and T3. One of the second metal lines and one of the fourth metal lines are connected to each other, cooperatively serve as a word line, and are further connected to the SRAM cell.

In accordance with some embodiments of the present disclosure, three of the first metal lines respectively serve as a non-inverting bit line, an inverting bit line, and a supply line that is for transmission of a supply voltage, and are connected to the SRAM cell. One of the third metal lines serves as a ground line that is for transmission of a ground voltage, and is connected to the SRAM cell.

In accordance with some embodiments of the present disclosure, the gate electrodes of the transistors have a minimum pitch of PG, the second metal lines have a minimum pitch of P2, and P2 is substantially equal to PG.

In accordance with some embodiments of the present disclosure, T2 is greater than any one of T4 and T5.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a plurality of transistors disposed on the substrate, and each including a gate electrode that extends in a first direction;
a first metal layer disposed over the transistors, and including a plurality of first metal lines, where each of the first metal lines extends in a second direction transverse to the first direction, and has a thickness of T1;
a second metal layer disposed over the first metal layer, and including a plurality of second metal lines, where each of the second metal lines extends in the first direction, and has a thickness of T2; and
a third metal layer disposed over the second metal layer, and including a plurality of third metal lines, where each of the third metal lines extends in the second direction, and has a thickness of T3;
wherein one of T2/T1 and T2/T3 is greater than or equal to 1.2.

2. The semiconductor device according to claim 1, wherein:
the gate electrodes of the transistors have a minimum pitch of PG;
the second metal lines have a minimum pitch of P2; and
P2 is substantially equal to PG.

3. The semiconductor device according to claim 1, further comprising:
a via layer disposed between the third metal layer and the second metal layer, and including a plurality of vias;
wherein each of the vias has an elongated shape oriented in the second direction, and has a length of L2 in the second direction and a width of W2 in the first direction; and
wherein 1.1≤L2/W2≤3.

4. The semiconductor device according to claim 1, further comprising:
a fourth metal layer disposed over the third metal layer, and including a plurality of fourth metal lines, where each of the fourth metal lines extends in the first direction, and has a thickness of T4; and
a fifth metal layer disposed over the fourth metal layer, and including a plurality of fifth metal lines, where each of the fifth metal lines extends in the second direction, and has a thickness of T5;
wherein T2 is greater than any one of T1, T3, T4 and T5.

5. The semiconductor device according to claim 4, further comprising:
a sixth metal layer disposed over the fifth metal layer, and including a plurality of sixth metal lines, where each of the sixth metal lines extends in the first direction, and has a thickness of T6;
wherein T6<T2.

6. The semiconductor device according to claim 4, further comprising:
a bottom via layer disposed over the transistors and below the first metal layer, and including a plurality of first contact vias and a plurality of second contact vias;
wherein each of the first contact vias is connected to one of the first metal lines, the second metal lines, the third metal lines, the fourth metal lines and the fifth metal lines that is not for transmission of either a supply voltage or a ground voltage, and has a top area of A1;
wherein each of the second contact vias is connected to one of the first metal lines, the second metal lines, the third metal lines, the fourth metal lines and the fifth metal lines that is for transmission of one of the supply voltage and the ground voltage, and has a top area of A2; and
wherein 1.2≤A2/A1≤5.

7. The semiconductor device according to claim 4, wherein:
the first metal lines have a minimum pitch of P1, the second metal lines have a minimum pitch of P2, the third metal lines have a minimum pitch of P3, the fourth metal lines have a minimum pitch of P4, and the fifth metal lines have a minimum pitch of P5;
P2>P5>P4>P3>P1; and
each of T2/T5, T5/T4, T4/T3 and T3/T1 falls within a range of from 1.05 to 2.

8. The semiconductor device according to claim 4, wherein:
the first metal lines have a minimum pitch of P1, the second metal lines have a minimum pitch of P2, the third metal lines have a minimum pitch of P3, the fourth metal lines have a minimum pitch of P4, and the fifth metal lines have a minimum pitch of P5;
P2>P4>P5>P3>P1; and
each of T2/T4, T4/T5, T5/T3 and T3/T1 falls within a range of from 1.05 to 2.

9. The semiconductor device according to claim 4, wherein:
the gate electrodes of the transistors have a minimum pitch of PG;
the fourth metal lines have a minimum pitch of P4; and
P4 is substantially equal to three-fourths of PG.

10. The semiconductor device according to claim 4, wherein:
the gate electrodes of the transistors have a minimum pitch of PG that falls within a range of from 36 nm to 52 nm;
the first metal lines have a minimum pitch of P1 that falls within a range of from 15 nm to 26 nm;
the second metal lines have a minimum pitch of P2 that falls within a range of from 36 nm to 52 nm;
the third metal lines have a minimum pitch of P3 that falls within a range of from 22 nm to 32 nm;
the fourth metal lines have a minimum pitch of P4 that falls within a range of from 32 nm to 52 nm; and
the fifth metal lines have a minimum pitch of P5 that falls within a range of from 35 nm to 44 nm.

11. A semiconductor device comprising:
a substrate;
a plurality of transistors disposed on the substrate, and each including a gate electrode that extends in a first direction;
a first metal layer disposed over the transistors, and including a plurality of first metal lines, where each of the first metal lines extends in a second direction transverse to the first direction, and the first metal lines have a minimum width of W1;
a second metal layer disposed over the first metal layer, and including a plurality of second metal lines, where each of the second metal lines extends in the first direction, and the second metal lines have a minimum width of W2; and
a third metal layer disposed over the second metal layer, and including a plurality of third metal lines, where each of the third metal lines extends in the second direction, and the third metal lines have a minimum width of W3;
wherein each of W2/W1 and W2/W3 is greater than or equal to 1.2.

12. The semiconductor device according to claim 11, wherein:
the gate electrodes of the transistors have a minimum pitch of PG;
the second metal lines have a minimum pitch of P2; and
P2 is substantially equal to PG.

13. The semiconductor device according to claim 11, further comprising:
a fourth metal layer disposed over the third metal layer, and including a plurality of fourth metal lines, where each of the fourth metal lines extends in the first direction, and has a thickness of T4; and
a fifth metal layer disposed over the fourth metal layer, and including a plurality of fifth metal lines, where each of the fifth metal lines extends in the second direction, and has a thickness of T5;
wherein each of the first metal lines has a thickness of T1;
wherein each of the second metal lines has a thickness of T2;
wherein each of the third metal lines has a thickness of T3; and
wherein T2 is greater than any one of T1 and T3, and T4 is greater than any one of T3 and T5.

14. The semiconductor device according to claim 13, wherein:
the gate electrodes of the transistors have a minimum pitch of PG;
the fourth metal lines have a minimum pitch of P4; and
P4 is substantially equal to three-fourths of PG.

15. The semiconductor device according to claim 13, wherein:
the gate electrodes of the transistors have a minimum pitch of PG;
the fourth metal lines have a minimum pitch of P4; and
P4 is substantially equal to PG.

16. The semiconductor device according to claim 13, wherein:
the gate electrodes of the transistors have a minimum pitch of PG that falls within a range of from 36 nm to 52 nm;
the first metal lines have a minimum pitch of P1 that falls within a range of from 18 nm to 26 nm;
the second metal lines have a minimum pitch of P2 that falls within a range of from 36 nm to 52 nm;
the third metal lines have a minimum pitch of P3 that falls within a range of from 22 nm to 32 nm;
the fourth metal lines have a minimum pitch of P4 that falls within a range of from 36 nm to 52 nm; and
the fifth metal lines have a minimum pitch of P5 that falls within a range of from 35 nm to 44 nm.

17. A semiconductor device comprising:
a substrate;
a static random access memory (SRAM) cell disposed on the substrate, and including a plurality of transistors, where each of the transistors includes a gate electrode that extends in a first direction;
a first metal layer disposed over the SRAM cell, and including a plurality of first metal lines, where each of the first metal lines extends in a second direction transverse to the first direction, and has a thickness of T1;
a second metal layer disposed over the first metal layer, and including a plurality of second metal lines, where each of the second metal lines extends in the first direction, and has a thickness of T2;
a third metal layer disposed over the second metal layer, and including a plurality of third metal lines, where each of the third metal lines extends in the second direction, and has a thickness of T3;
a fourth metal layer disposed over the third metal layer, and including a plurality of fourth metal lines, where each of the fourth metal lines extends in the first direction, and has a thickness of T4; and
a fifth metal layer disposed over the fourth metal layer, and including a plurality of fifth metal lines, where each of the fifth metal lines extends in the second direction, and has a thickness of T5;
wherein T2 is greater than any one of T1 and T3; and
wherein one of the second metal lines and one of the fourth metal lines are connected to each other, cooperatively serve as a word line, and are further connected to the SRAM cell.

18. The semiconductor device according to claim 17, wherein:
three of the first metal lines respectively serve as a non-inverting bit line, an inverting bit line, and a supply line that is for transmission of a supply voltage, and are connected to the SRAM cell; and
one of the third metal lines serves as a ground line that is for transmission of a ground voltage, and is connected to the SRAM cell.

19. The semiconductor device according to claim 17, wherein:
the gate electrodes of the transistors have a minimum pitch of PG;
the second metal lines have a minimum pitch of P2; and
P2 is substantially equal to PG.

20. The semiconductor device according to claim 17, wherein T2 is greater than any one of T4 and T5.
